(19) United States
(12) Patent Application Publication
(10) Pub. No.: US 2025/0212491 A1
(43) Pub. Date: Jun. 26, 2025

(54) SEMICONDUCTOR DEVICE INCLUDING DIELECTRIC LAYER WITH UNEVEN THICKNESS

(71) Applicant: NANYA TECHNOLOGY CORPORATION, NEW TAIPEI CITY (TW)

(72) Inventor: CHAO-WEN LAY, NEW TAIPEI CITY (TW)

(21) Appl. No.: 18/395,797

(22) Filed: Dec. 26, 2023

(51) Int. Cl. H01L 29/51; H01L 29/423

(52) U.S. Cl. CPC H10D 64/685; H10D 64/513

(57) ABSTRACT

A semiconductor device and method for manufacturing the same are provided. The semiconductor device includes a substrate, a dielectric layer, and a gate electrode. The dielectric layer is at least partially embedded within the substrate. The dielectric layer has a first portion with a first thickness and a second portion with a second thickness less than the first thickness. The gate electrode is spaced apart from the substrate by the first portion of the dielectric layer.

### TECHNICAL FIELD

The present disclosure relates to a semiconductor device and method for manufacturing the same, and more particularly, to a semiconductor device including a dielectric layer with an uneven thickness and method for manufacturing the same.

### DISCUSSION OF THE BACKGROUND

With integrated circuits (ICs) achieving regular increases in performance and miniaturization, advances in materials and design produce successive generations with smaller and more complex circuits.

As the semiconductor industry develops, the aspect ratio of trenches of a substrate increases, which has a negatively influence on the formation of a gate electrode within the trench of the substrate. For example, the bottom of the trench may have voids so that the electrical properties fail to meet actual requirements. Therefore, a new semiconductor device and method of improving such problems is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a dielectric layer, and a gate electrode. The dielectric layer is at least partially embedded within the substrate. The dielectric layer has a first portion with a first thickness and a second portion with a second thickness less than the first thickness. The gate electrode is spaced apart from the substrate by the first portion of the dielectric layer.

Another aspect of the present disclosure provides a semiconductor device. The semiconductor device includes a substrate, a gate dielectric layer, a gate electrode, and a dielectric structure. The gate dielectric is embedded within the substrate. The gate electrode is spaced apart from the substrate by the gate dielectric. The dielectric structure is disposed over the gate electrode. The dielectric structure includes a step profile.

Another aspect of the present disclosure provides a method of manufacturing a semiconductor device. The method includes providing a substrate with a trench. The method also includes forming a dielectric layer with a first thickness within the trench. The method further includes removing an upper portion of the dielectric layer so that the upper portion of the dielectric layer has a second thickness less than the first thickness of a lower portion of the dielectric layer. In addition, the method includes forming a gate electrode within the trench.

The embodiments of the present disclosure illustrate a semiconductor device including a dielectric layer located within a trench defined by a substrate. The dielectric layer has a lower portion with a greater thickness and an upper portion with a smaller thickness. Such structure can facilitate filling a conductive material(s) to form a gate electrode without voids formed within the trench. As a result, the performance of the semiconductor device is enhanced.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

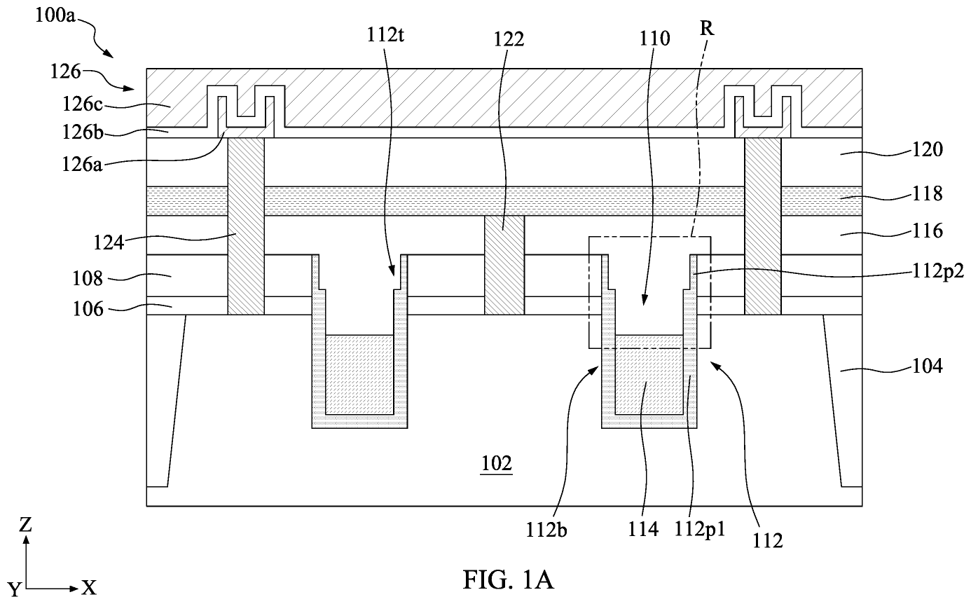

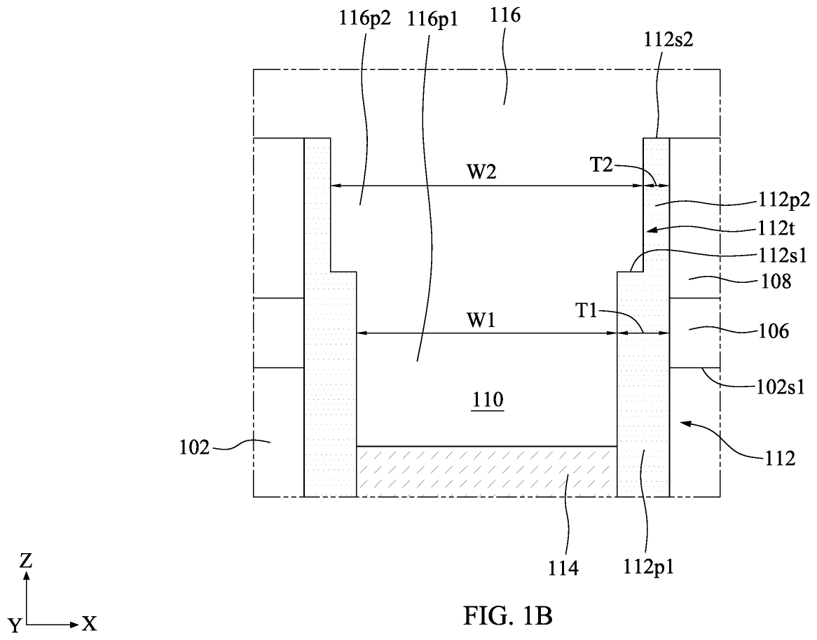

FIG. 1A is a cross-sectional view of a semiconductor device, in accordance with some embodiments of the present disclosure.

FIG. 1B is a partial enlarged view of a region R of the semiconductor device as shown in FIG. 1A, in accordance with some embodiments of the present disclosure.

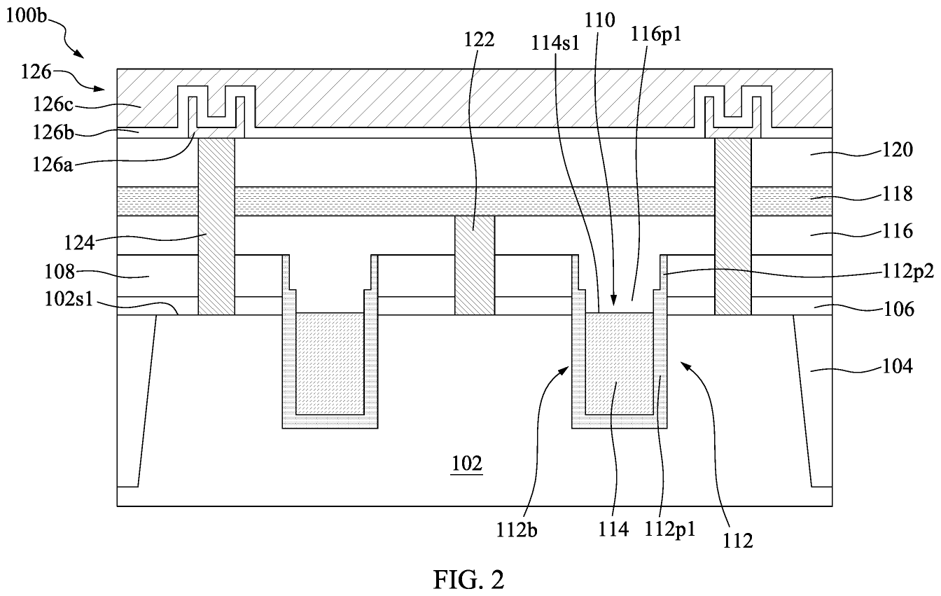

FIG. 2 is a cross-sectional view of a semiconductor device, in accordance with some embodiments of the present disclosure.

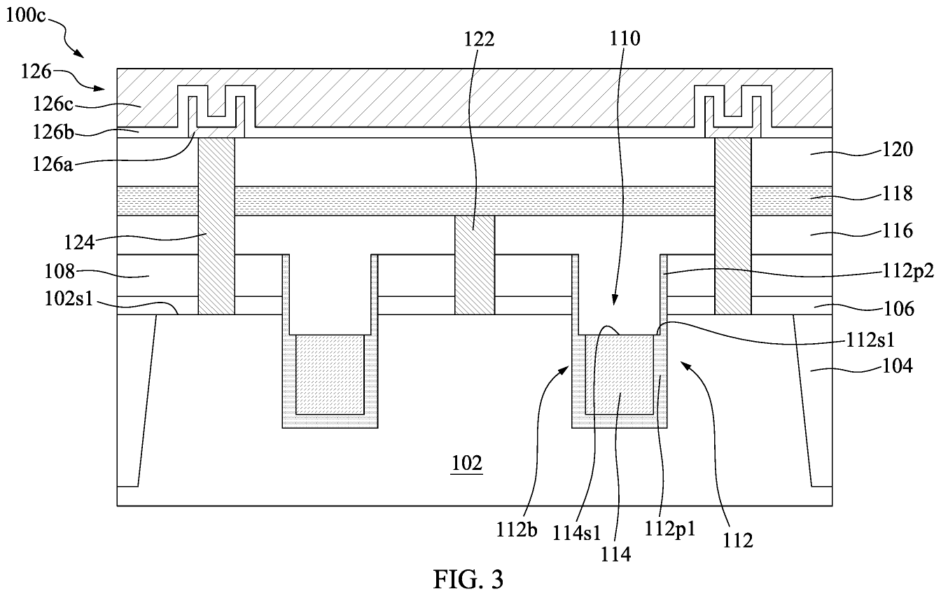

FIG. 3 is a cross-sectional view of a semiconductor device, in accordance with some embodiments of the present disclosure.

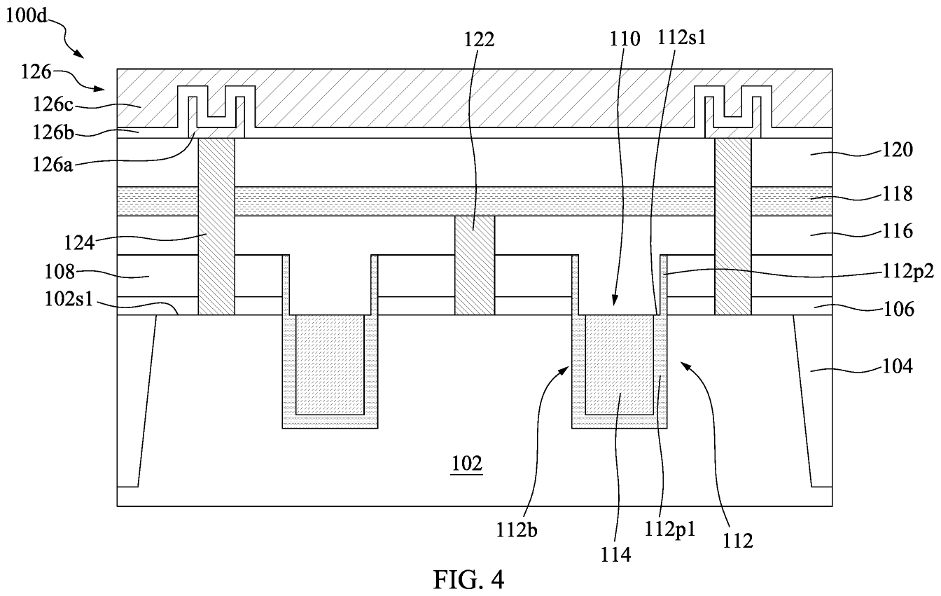

FIG. 4 is a cross-sectional view of a semiconductor device, in accordance with some embodiments of the present disclosure.

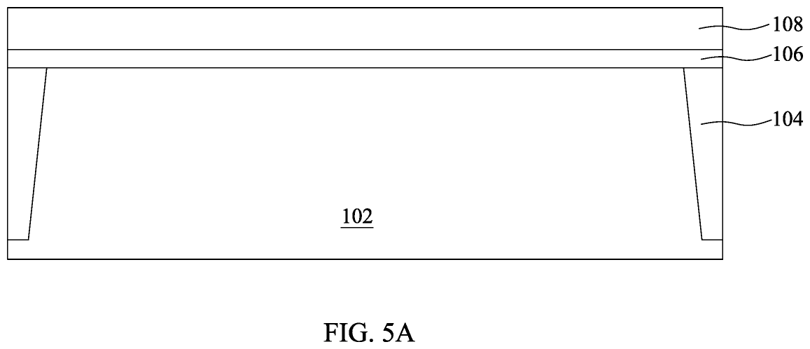

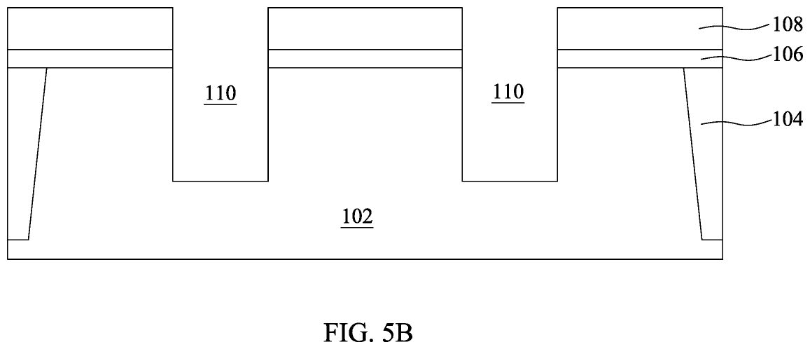

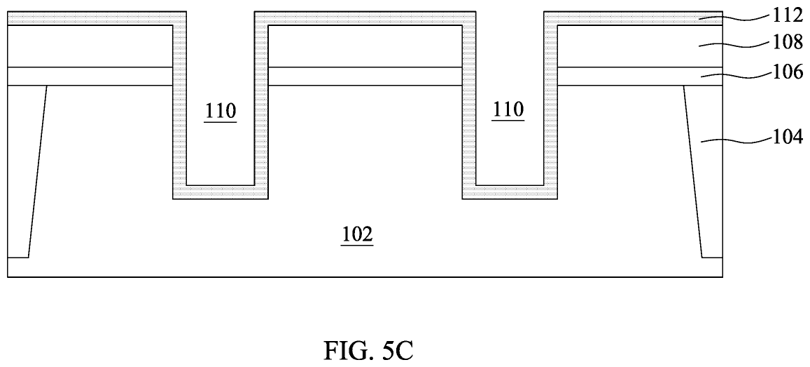

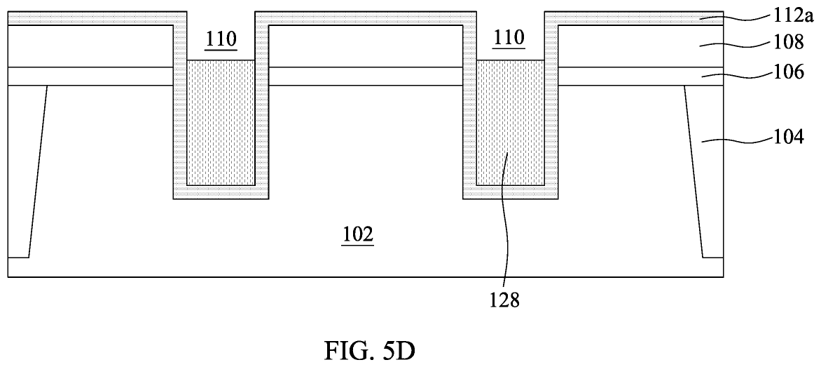

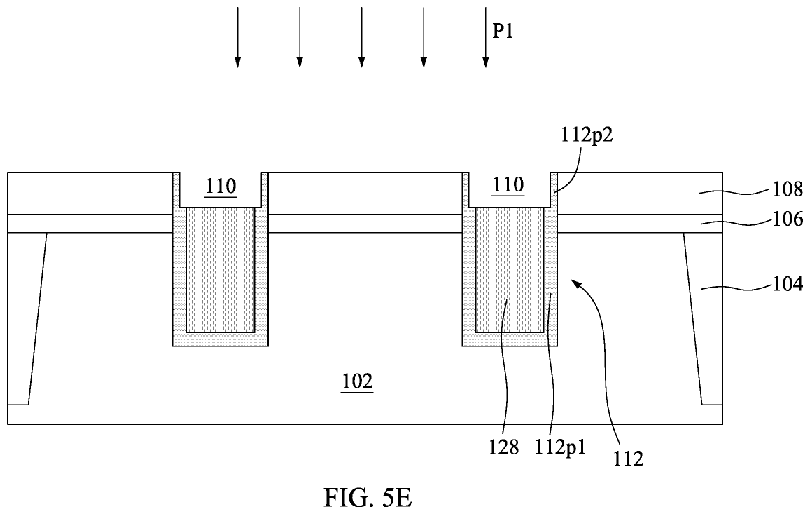

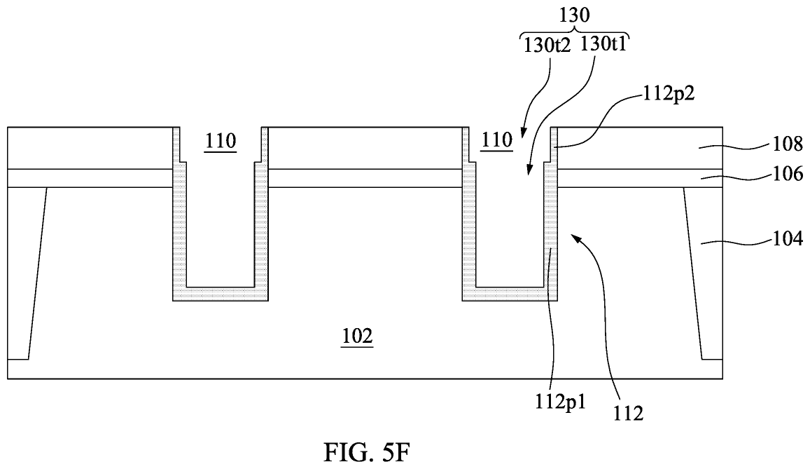

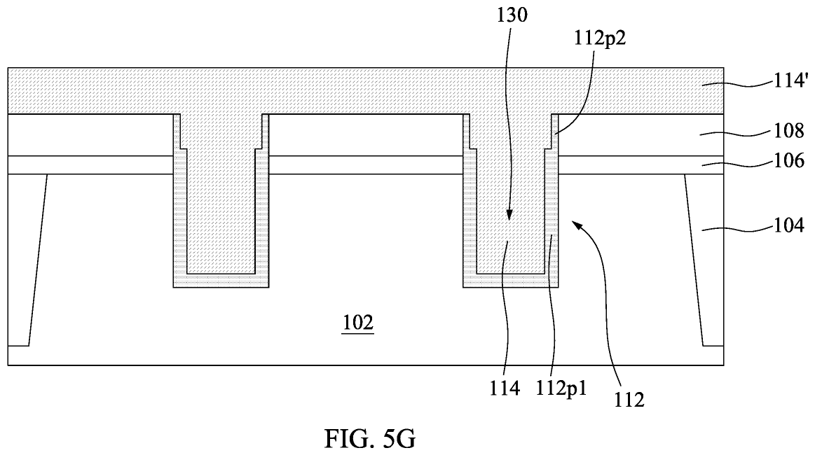

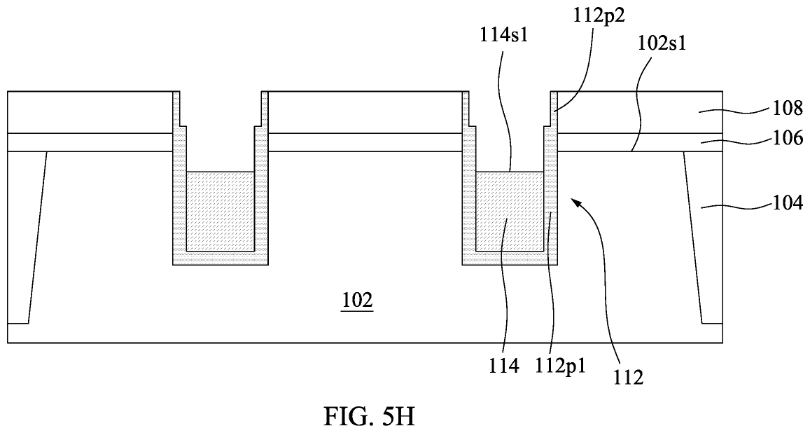

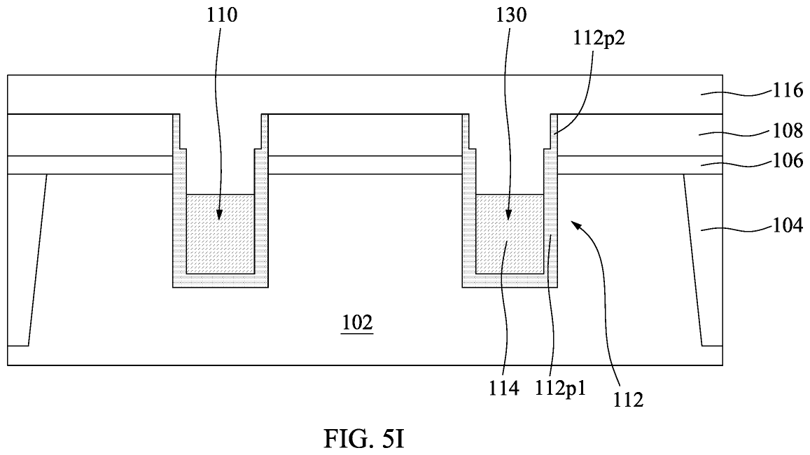

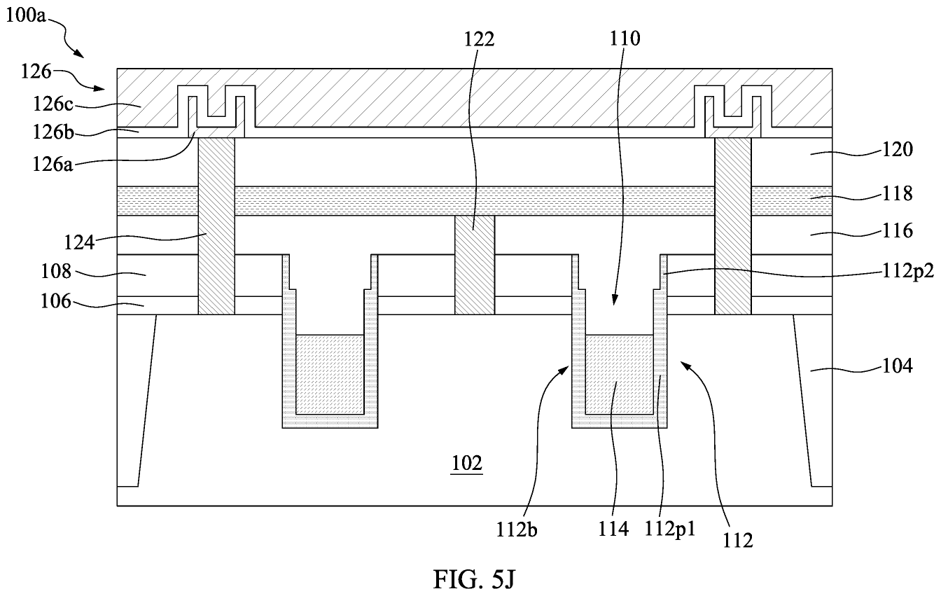

FIG. 5A illustrates one or more stages of an exemplary method for manufacturing a semiconductor device according to some embodiments of the present disclosure.

FIG. 5B illustrates one or more stages of an exemplary method for manufacturing a semiconductor device according to some embodiments of the present disclosure.

FIG. 5C illustrates one or more stages of an exemplary method for manufacturing a semiconductor device according to some embodiments of the present disclosure.

FIG. 5D illustrates one or more stages of an exemplary method for manufacturing a semiconductor device according to some embodiments of the present disclosure.

FIG. 5E illustrates one or more stages of an exemplary method for manufacturing a semiconductor device according to some embodiments of the present disclosure.

FIG. 5F illustrates one or more stages of an exemplary method for manufacturing a semiconductor device according to some embodiments of the present disclosure.

FIG. 5G illustrates one or more stages of an exemplary method for manufacturing a semiconductor device according to some embodiments of the present disclosure.

FIG. 5H illustrates one or more stages of an exemplary method for manufacturing a semiconductor device according to some embodiments of the present disclosure.

FIG. 5I illustrates one or more stages of an exemplary method for manufacturing a semiconductor device according to some embodiments of the present disclosure.

FIG. 5J illustrates one or more stages of an exemplary method for manufacturing a semiconductor device according to some embodiments of the present disclosure.

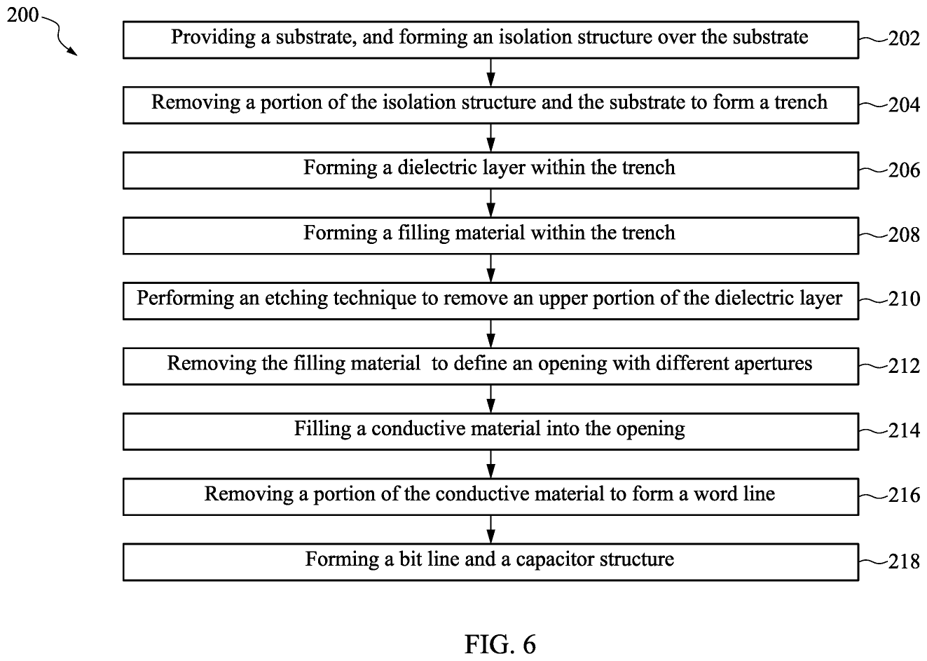

FIG. 6 is a flowchart illustrating a method of manufacturing a semiconductor device, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1A is a cross-sectional view of a semiconductor device 100a, in accordance with some embodiments of the present disclosure. In some embodiments, the semiconductor device 100a may include a cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. In some embodiments, the semiconductor device 100a may include a peripheral region in which a transistor is formed.

During a read operation, a word line may be asserted, turning on the transistor. The enabled transistor allows the voltage across the capacitor to be read by a sense amplifier through a bit line. During a write operation, the data to be written may be provided on the bit line when the word line is asserted.

The semiconductor device 100a may include a substrate 102. The substrate 102 may be a semiconductor substrate, such as a bulk semiconductor, a semiconductor-on-insulator (SOI) substrate, or the like. The substrate 102 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 102 may have a multilayered structure, or the substrate 102 may include a multilayered compound semiconductor structure.

In some embodiments, the substrate 102 may include a plurality of active areas (not shown). The active area may function as, for example, a channel for electrical connection. In some embodiments, dopants (not shown) may be doped into the substrate 102 to form said active region. In some embodiments, the dopants may be an n type and/or p type. In some embodiments, n type dopants include arsenic (As), phosphorus (P), other group V elements, or any combination thereof. In some embodiments, the first conductive type is a p type. In some embodiments, p type dopants include boron (B), other group III elements, or any combination thereof.

In some embodiments, the semiconductor device 100a may include an electrical isolation region 104. In some embodiments, the electrical isolation region 104 may include a shallow trench isolation (STI). In some embodiments, the plurality of active areas may be separated by the electrical isolation region 104. In some embodiments, the electrical isolation region 104 may be embedded in the substrate 102. In some embodiments, the electrical isolation region 104 may include, for example, silicon oxide (SiO₂), silicon nitride (Si₃N₄), silicon oxynitride (N₂OSi₂), silicon nitride oxide (N₂OSi₂), or other suitable materials.

In some embodiments, the semiconductor device 100a may include a dielectric layer 106. The dielectric layer 106 may be disposed on the substrate 102. In some embodiments, the dielectric layer 106 may cover the electrical isolation region 104. In some embodiments, the dielectric layer 106 may include, for example, silicon oxide (SiO₂), silicon nitride (Si₃N₄), silicon oxynitride (N₂OSi₂), silicon nitride oxide (N₂OSi₂), or other suitable materials.

In some embodiments, the semiconductor device 100a may include a dielectric layer 108. The dielectric layer 108 may be disposed on the dielectric layer 106. In some embodiments, the dielectric layer 108 may include, for example, silicon nitride (Si₃N₄), silicon oxide (SiO₂), silicon oxynitride (N₂OSi₂), silicon nitride oxide (N₂OSi₂), or other suitable materials. In some embodiments, the dimension (e.g., thickness) of the dielectric layer 106 may be different from that of the dielectric layer 108. For example, the thickness of the dielectric layer 108 may be greater than that of the dielectric layer 106. In some embodiments, the material of the dielectric layer 108 may be different from that of the dielectric layer 106. For example, the dielectric layer 106 may include or be made of silicon oxide (SiO₂), and the dielectric layer 108 may include or be made of silicon nitride (Si₃N₄). In some embodiments, either the dielectric layer 106, the dielectric layer 108, or both may be referred to as an isolation structure.

In some embodiments, the substrate 102, the dielectric layer 106, and/or the dielectric layer 108 may define trenches 110. The trench 110 may penetrate a portion of the substrate 102. The trench 110 may penetrate the dielectric layer 106. The trench 110 may penetrate the dielectric layer 108. The trench 110 may be configured to accommodate a gate stack, which includes a gate dielectric, a gate electrode, and/or other suitable elements.

In some embodiments, the semiconductor device 100a may include a dielectric layer 112. In some embodiments, the dielectric layer 112 may be disposed within the trench 110. In some embodiments, the dielectric layer 112 may be disposed on the sidewall (or lateral surface) of the substrate 102. In some embodiments, the dielectric layer 112 may be disposed on the lower surface of the substrate 102. In some embodiments, the dielectric layer 112 may be in contact with the substrate 102. In some embodiments, the dielectric layer 112 may be disposed on the sidewall (or lateral surface) of the dielectric layer 106. In some embodiments, the dielectric layer 112 may be in contact with the dielectric layer 106. In some embodiments, the dielectric layer 112 may be disposed on the sidewall (or lateral surface) of the dielectric layer 108. In some embodiments, the dielectric layer 112 may be in contact with the dielectric layer 108.

In some embodiments, the dielectric layer 112 may include, for example, silicon nitride (Si₃N₄), silicon oxide (SiO₂), silicon oxynitride (N₂OSi₂), silicon nitride oxide (N₂OSi₂), or other high-k materials. Examples of the high-k material include a dielectric material having a dielectric constant exceeding that of silicon dioxide (SiO₂), or a dielectric material having a dielectric constant higher than about 3.9. In some embodiments, the dielectric layer 112 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

In some embodiments, the semiconductor device 100a may include a gate electrode 114. In some embodiments, the gate electrode 114 may be disposed within the trench 110. The gate electrode 114 may be disposed on the dielectric layer 112. The gate electrode 114 may be spaced apart from the substrate 102 by the dielectric layer 112. The gate electrode 114 may include one or more materials. For example, the gate electrode 114 may include a barrier layer and a conductive layer spaced apart from the dielectric layer 112 by the barrier layer. The barrier layer may include titanium (Ti), titanium nitride (TiN), tantalum (Ta), tantalum nitride (TaN), tungsten nitride (WN), tungsten carbon nitride (WCN), or the like. In some example embodiments, the conductive layer may include tungsten (W), aluminum (Al), copper (Cu), other suitable materials, or a combination thereof. In some embodiments, the gate electrode 114 may include multiple barrier layers and multiple conductive layers separated by the barrier layers. In some embodiments, the gate electrode 114 may function as a word line structure of a DRAM device. The gate electrode 114 may extend along the Y direction. In some embodiments, a portion of the dielectric layer 112 may function as a gate dielectric 112b.

In some embodiments, the semiconductor device 100a may include a dielectric structure 116. The dielectric structure 116 may be disposed on the dielectric layer 108. A portion of the dielectric structure 116 may be disposed within the trench 110. The dielectric structure 116 may cover the gate electrode 114. In some embodiments, the dielectric structure 116 may be in contact with the sidewall of the dielectric layer 112. In some embodiments, the dielectric structure 116 may include, for example, silicon nitride (Si₃N₄), silicon oxide (SiO₂), silicon oxynitride (N₂OSi₂), silicon nitride oxide (N₂OSi₂), other suitable materials, or a combination thereof. In some embodiments, the material of the dielectric structure 116 may be different from that of the dielectric layer 112. For example, the dielectric structure 116 may include or be made of silicon nitride (Si₃N₄), and the dielectric layer 112 may include or be made of silicon oxide (SiO₂).

In some embodiments, the semiconductor device 100a may include a bit line structure 118. The bit line structure 118 may be disposed on the dielectric structure 116. The bit line structure 118 may be disposed over the word line, which includes the gate electrode 114. The bit line structure 118 may extend along the X direction. In some embodiments, the bit line structure 118 may include a multilayered structure. For example, the bit line structure 118 may include a conductive layer including polysilicon doped with n type dopants, such as arsenic (As) or phosphorus (P). The bit line structure 118 may also include titanium (Ti), tungsten (W), aluminum (Al), copper (Cu), other suitable materials, or a combination thereof.

In some embodiments, the semiconductor device 100a may include an isolation layer 120. The isolation layer 120 may be disposed on the bit line structure 118. The isolation layer 120 may include, silicon nitride (Si₃N₄), silicon oxide (SiO₂), silicon oxynitride, flowable oxide, tonen silazen, undoped silica glass, borosilica glass, phosphosilica glass, borophosphosilica glass, plasma-enhanced tetraethyl orthosilicate, fluoride silicate glass, carbon-doped silicon oxide, or a combination thereof. The isolation layer 120 may function as a hard mask configured to prevent the bit line structure 118 from damage in the stages of, for example, forming capacitor structures.

In some embodiments, the semiconductor device 100a may include a conductive contact 122. The conductive contact 122 may penetrate the dielectric structure 116. The conductive contact 122 may penetrate the dielectric layer 108. The conductive contact 122 may penetrate the dielectric layer 106. The conductive contact 122 may be configure to electrically connect the active region (e.g., the doped region within the substrate 102) and the bit line structure 118. The conductive contact 122 may include, for example, tungsten (W), cobalt (Co), zirconium (Zr), tantalum (Ta), titanium (Ti), aluminum (Al), ruthenium (Ru), copper (Cu), metal carbides (e.g., tantalum carbide (TaC), titanium carbide (TiC), tantalum magnesium carbide (TaMaC)), metal nitrides (e.g., titanium nitride (TiN)), transition metal aluminides, or a combination thereof.

In some embodiments, the semiconductor device 100a may include a conductive contact 124. The conductive contact 124 may penetrate the isolation layer 120. The conductive contact 124 may penetrate the dielectric structure 116. The conductive contact 124 may penetrate the dielectric layer 108. The conductive contact 124 may penetrate the dielectric layer 106. The conductive contact 124 may be configure to electrically connect the active region (e.g., the doped region within the substrate 102) and a capacitor structure (e.g., capacitor structure 126). The conductive contact 124 may include, for example, tungsten (W), cobalt (Co), zirconium (Zr), tantalum (Ta), titanium (Ti), aluminum (Al), ruthenium (Ru), copper (Cu), metal carbides (e.g., tantalum carbide (TaC), titanium carbide (TIC), tantalum magnesium carbide (TaMaC)), metal nitrides (e.g., titanium nitride (TiN)), transition metal aluminides, or a combination thereof. It should be noted that the conductive contact 124 and the bit line structure 118 have a distance therebetween along the Y direction.

In some embodiments, the semiconductor device 100a may include a capacitor structure 126. The capacitor structure 126 may be disposed on the isolation layer 120. The capacitor structure 126 may be disposed over the bit line structure 118. The capacitor structure 126 may be electrically connected to the active region (e.g., the doped region within the substrate 102) by the conductive contact 124. The capacitor structure 126 may include a capacitor electrode 126a, a capacitor dielectric 126b, and a capacitor electrode 126c.

The capacitor electrode 126a may be disposed on the conductive contact 124. The capacitor electrode 126a may be electrically connected to the conductive contact 124. The capacitor electrode 126a may function as a lower electrode of the capacitor structure 126. In some embodiments, the capacitor electrode 126a may have multiple vertical portions connected by horizontal portions to increase the capacitance of the capacitor structure 126. In some embodiments, the capacitor electrode 126a may include tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or combinations thereof.

The capacitor dielectric 126b may be disposed between the capacitor electrode 126a and capacitor electrode 126c. The capacitor dielectric 126b may be conformally disposed on the capacitor electrode 126a. The capacitor dielectric 126b may include silicon oxide (SiO₂), silicon nitride (Si₃N₄), silicon oxynitride (N₂OSi₂), silicon nitride oxide (N₂OSi₂), or other suitable materials.

The capacitor electrode 126c may be disposed on the capacitor dielectric 126b. The capacitor electrode 126c may function as an upper electrode of the capacitor structure 126. In some embodiments, the capacitor electrode 126c may include tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or combinations thereof.

Although not shown, it should be noted that the semiconductor device 100a may further include other components. For example, the semiconductor device 100a may include a spacer surrounding the conductive contact 122 and/or conductive contact 124. The spacer may include multiple dielectric layers, such as silicon oxide, silicon nitride, silicon oxynitride, silicon nitride oxide, a high-k material or combinations thereof. The spacer may further include an air gap between dielectric layers. A landing pad may cover the air gap. Said landing pad may be electrically connected to the capacitor structure 126. The landing pad may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, or combinations thereof.

Please refer to FIG. 1B, which is a partial enlarged view of a region R of the semiconductor device as shown in FIG. 1A.

In some embodiments, the dielectric layer 112 may include a portion 112p1 (or a lower portion) and a portion 112p2 (or an upper portion) over the portion 112p1. The portion 112p1 and the portion 112p2 may have different dimensions (e.g., a thickness or a length along the X direction). For example, the portion 112p1 may have a thickness T1, and the portion 112p2 may have a thickness T2 less than the thickness T1. In some embodiments, a ratio of the thickness T1 to the thickness T2 may range from about 0.2 to about 0.8, such as 0.2, 0.3, 0.4, 0.5, 0.6, 0.7, or 0.8. When the ratio of the thickness T1 to the thickness T2 ranges from 0.2 to 0.8, the opening defined by the dielectric layer 112 may have a relatively suitable aspect ratio, which facilitates the formation of the gate electrode 114 and will be described in detail later.

In some embodiments, the portion 112p1 and the portion 112p2 of the dielectric layer 112 may define a step structure 112t. In some embodiments, the step structure 112t may be located over the gate electrode 114. The step structure 112t may define an opening with different aspect ratios. In some embodiments, the step structure 112t may overlap along the dielectric layer 118.

In some embodiments, the gate electrode 114 may be disposed on the sidewall of the portion 112p1 of the dielectric layer 112. In some embodiments, the gate electrode 114 may be in contact with the portion 112p1 of the dielectric layer 112. In some embodiments, a surface 112s1 (or an upper surface) of the portion 112p1 of the dielectric layer 112 may be located at an elevation higher than a surface 102s1 (or an upper surface) of the substrate 102. In some embodiments, the portion 112p1 of the dielectric layer 112 may be in contact with or overlap the sidewall of the substrate 102 along the X direction. In some embodiments, the portion 112p1 of the dielectric layer 112 may be in contact with or overlap the sidewall of the dielectric layer 106 along the X direction. In some embodiments, the portion 112p1 of the dielectric layer 112 may be in contact with or overlap a portion of the sidewall of the dielectric layer 108 along the X direction.

The portion 112p2 is connected to and located directly over the portion 112p1. A surface 112s2 (or an upper surface) of the portion 112p2 may be located at an elevation higher than that of the surface 112s1 of the dielectric layer 112. In some embodiments, the surface 112s2 of the dielectric layer 112 may be located at an elevation higher than the surface 102s1 of the substrate 102. In some embodiments, the surface 112s1 may be exposed by the portion 112p2. In some embodiments, the surface 112s2 of the dielectric layer 112 may be located at an elevation substantially the same as that of the upper surface (not annotated) of the dielectric layer 108 (or isolation structure). In some embodiments, a length of the portion 112p2 along the Z direction may be less than that of the portion 112p1. In some embodiments, the portion 112p2 of the dielectric layer 112 may be in contact with or overlap a portion of the sidewall of the dielectric layer 108 along the X direction. In some embodiments, the portion 112p2 of the dielectric layer 112 may be spaced apart from the gate electrode 114.

In some embodiments, the dielectric structure 116 within the trench 110 may have a T-shaped profile. In some embodiments, the dielectric structure 116 may have a step profile corresponding to the step 112t of the dielectric layer 112. In some embodiments, the dielectric structure 116 may have a portion 116p1 and a portion 116p2 over the portion 116p1. The portion 116p1 may be located over the gate electrode 114. The portion 116p2 may be located over the portion 116p1. The portion 116p1 of the dielectric structure 116 may be in contact with the portion 112p1 of the dielectric layer 112. The portion 116p2 of the dielectric structure 116 may be in contact with the portion 112p2 of the dielectric layer 112. In some embodiments, the portion 116p1 may overlap the substrate 102 along the X direction. In some embodiments, the portion 116p1 may overlap the dielectric layer 106 along the X direction. In some embodiments, the portion 116p1 may overlap a portion of the dielectric layer 108 along the X direction. In some embodiments, the portion 116p2 may overlap a portion of the dielectric layer 108 along the X direction. The portion 116p1 of the dielectric structure 116 may have a width (or aperture) W1 along the X direction. The portion 116p2 of the dielectric structure 116 may have a width (or aperture) W2 along the X direction. In some embodiments, the width W2 may be greater than the width W1. In some embodiments, a ratio of the width W2 to the width W1 may range from about 1.1 to about 1.5, such as 1.1, 1.2, 1.3, 1.4, or 1.5. In some embodiments, the ratio of the width (or aperture) defined by the portion 112p2 to the width (or aperture) defined by the portion 112p1 may from about 1.1 to about 1.5, such as 1.1, 1.2, 1.3, 1.4, or 1.5, which thereby facilitates the formation of depositing the materials of the gate electrode 114.

FIG. 2 is a cross-sectional view of a semiconductor device 100b, in accordance with some embodiments of the present disclosure. The semiconductor device 100b is similar to the semiconductor device 100a, with differences therebetween as follows.

In some embodiments, a surface 114s1 (or an upper surface) of the gate electrode 114 may be located at an elevation substantially the same as that of the surface 102s1 of the substrate 102. In some embodiments, the portion 116p1 of the dielectric structure 116 may be free from overlapping the substrate 102 along the X direction. In some embodiments, the lower surface of the dielectric structure 116 may be located at an elevation substantially the same as that of the surface 102s1 of the substrate 102.

FIG. 3 is a cross-sectional view of a semiconductor device 100c, in accordance with some embodiments of the present disclosure. The semiconductor device 100c is similar to the semiconductor device 100a, with differences therebetween as follows.

In some embodiments, the surface 114s1 of the gate electrode 114 may be substantially aligned with or coplanar with the surface 112s1 of the dielectric layer 112. In some embodiments, the surface 102s1 of the substrate 102 may be located at an elevation higher than that of the surface 112s1 of the dielectric layer 112. In some embodiments, the portion 112p2 of the dielectric layer 112 may overlap the dielectric layer 106 along the X direction. In some embodiments, the portion 112p2 of the dielectric layer 112 may overlap the substrate 102 along the X direction.

FIG. 4 is a cross-sectional view of a semiconductor device 100d, in accordance with some embodiments of the present disclosure. The semiconductor device 100d is similar to the semiconductor device 100a, with differences therebetween as follows.

In some embodiments, the surface 112s1 of the dielectric layer 112 may be located an elevation substantially the same as that of the surface 102s1 of the substrate 102. In some embodiments, the dielectric structure 116 within the trench 110 may have a substantially uniform width (or aperture) along the X direction. In some embodiments, the dielectric structure 116 may be free from overlapping the portion 112p1 of the dielectric layer 112.

FIG. 5A to FIG. 5J illustrate stages of an exemplary method for manufacturing a semiconductor device according to some embodiments of the present disclosure.

Referring to FIG. 5A, the substrate 102 may be provided. The electrical isolation region 104 may be formed within the substrate 102. The dielectric layer 106 may be formed on the electrical isolation region 104. The dielectric layer 108 may be formed on the dielectric layer 106. In some embodiments, an etching process may be performed to remove a portion of the substrate 102 to form a recess, and a dielectric material may be deposited within the recess to form the electrical isolation region 104. For example, the dielectric material may be deposited by chemical vapor deposition (CVD), atomic layer deposition (ALD), physical vapor deposition (PVD), low-pressure chemical vapor deposition (LPCVD), flowable chemical vapor deposition (FCVD), or other suitable process.

The dielectric layer 106 and the dielectric layer 108 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable process.

Referring to FIG. 5B, a trench 110 may be formed. In some embodiments, an etching technique(s) may be performed to remove a portion of the substrate 102, the dielectric layer 106, and the dielectric layer 108. The etching technique may include wet etching, dry etching, or other suitable techniques.

Referring to FIG. 5C, a dielectric material layer 112a may be formed to cover the upper surface of the dielectric layer 108 and the lateral surfaces of the substrate 102, the dielectric layer 106, and the dielectric layer 108. A portion of the dielectric material layer 112a may be located within the trench 110. The dielectric material layer 112a may be formed by chemical vapor deposition (CVD), atomic layer deposition (ALD), physical vapor deposition (PVD), low-pressure chemical vapor deposition (LPCVD), flowable chemical vapor deposition (FCVD), or other suitable process.

Referring to FIG. 5D, a filling material 128 may be formed within the trench 110. The filling material 128 may include a photosensitive material, such as photoresist or other suitable materials. The filling material 128 may cover a portion of the dielectric material layer 112a. In some embodiments, the filling material 128 may be formed by coating or other suitable techniques. In some embodiments, the filling material 128 may be formed over the dielectric layer 108 and fill the trench 110, and a portion of the filling material 128 may be removed by an etching technique so that the remaining portion of the upper surface of the filling material 128 is lower than the upper surface of the dielectric layer 108. In some embodiments, the upper surface of the filling material 128 may be higher than the surface 102s1 of the substrate 102. In some embodiments, the upper surface of the filling material 128 may be higher than the upper surface of the dielectric layer 106.

Referring to FIG. 5E, an etching technique P1 may be performed. As a result, a portion of the dielectric material layer 112a may be removed to define the dielectric layer 112. The portion 112p1 and the portion 112p2 may be formed. A portion of the dielectric material layer 112a over the filling material 128 may be partially removed so that the portion 112p1 and the portion 112p2 may have different thickness or length along the X direction. The etching technique P1 may include wet etching, dry etching, or other suitable techniques.

Referring to FIG. 5F, the filling material 128 may be removed. The dielectric layer 112 may define an opening 130. The opening 130 may have a part 130t1 and a part 130t2 over the part 130t1. The part 130t2 of the opening 130 has a greater aperture defined by the portion 112p2 of the dielectric layer 112. The part 130t1 of the opening 130 has a smaller aperture defined by the portion 112p1 of the dielectric layer 112. In some embodiments, a ratio of the aperture of the part 130t2 to the part 130t1 may range from about 1.1 to about 1.5, such as 1.1, 1.2, 1.3, 1.4, or 1.5.

Referring to FIG. 5G, the conductive material 114′ may be formed. In this stage, the greater aperture of the part 130t2 of the opening 130 facilitates filling the conductive material 114′, which allows the conductive material 114′ to fill into the bottom of the opening 130 with fewer or no voids. The conductive material 114′ may be formed by physical vapor deposition (PVD), chemical vapor deposition (CVD), atomic layer deposition (ALD), low-pressure chemical vapor deposition (LPCVD), flowable chemical vapor deposition (FCVD), or other suitable process.

Referring to FIG. 5H, a portion of the conductive material 114′ may be removed, and the gate electrode 114 is produced. The portion of the 112p1 and the portion 112p2 of the dielectric layer 112 may be exposed by the gate electrode 114. In some embodiments, the surface 114s1 of the gate electrode 114 may be lower than the surface 102s1 of the substrate 102. In other embodiments, the surface 114s1 of the gate electrode 114 may be substantially aligned with the surface 102s1 of the substrate 102 along the X direction. In other embodiments, additional conductive materials (not shown) may be formed over the gate electrode 114, and the upper surface of the additional conductive materials may be substantially aligned with the surface 102s1 of the substrate 102 along the X direction. The conductive material 114′ may be removed by an etching technique, such as fry etching, wet etching, or other suitable techniques.

Referring to FIG. 5I, the dielectric structure 116 may be formed. The dielectric structure 116 may fill the trench 110 or the opening 130. The dielectric structure 116 may cover the dielectric layer 108. The dielectric structure 116 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable process.

Referring to FIG. 5J, the bit line structure 118 may be formed over the dielectric structure 116. The isolation layer 120 may be formed over the bit line structure 118. The conductive contact 122 may be formed between the substrate 102 and the bit line structure 118. The conductive contact 124 may be formed to penetrate the dielectric structure 116 and the isolation layer 120. The capacitor structure 126, including the capacitor electrode 126a, the capacitor dielectric 126b, and the capacitor electrode 126c, may be formed over the isolation layer 120 and electrically connected to the conductive contact 124. As a result, a semiconductor device (e.g., the semiconductor device 100a as shown in FIG. 1A) may be produced.

FIG. 6 is a flowchart illustrating a method 200 of manufacturing a semiconductor device, in accordance with some embodiments of the present disclosure.

The method 200 begins with operation 202 in which a substrate is provided. An isolation structure is formed over the substrate. FIG. 5A illustrates the stage corresponding to operation 202.

The method 200 continues with operation 204 in which in which a portion of the isolation structure and the substrate are removed, which thereby forms a trench. FIG. 5B illustrates the stage corresponding to operation 204.

The method 200 continues with operation 206 in which a dielectric layer is formed within the trench. FIG. 5C illustrates the stage corresponding to operation 206.

The method 200 continues with operation 208 in which a filling material is formed within the trench. FIG. 5D illustrates the stage corresponding to operation 208.

The method 200 continues with operation 210 an etching technique is performed to remove an upper portion, exposed by the filling material, of the dielectric layer so that the lower portion of the dielectric layer has a greater thickness and the upper portion of the dielectric layer has a smaller thickness. FIG. 5E illustrates the stage corresponding to operation 210.

The method 200 continues with operation 212 in which the filling material is removed. An opening defined by the dielectric layer has a greater aperture at the upper portion and a smaller aperture at the lower portion. FIG. 5F illustrates the stage corresponding to operation 212.

The method 200 continues with operation 214 in which a conductive material is filled into the opening defined by the dielectric layer. FIG. 5G illustrates the stage corresponding to operation 214.

The method 200 continues with operation 216 in which a portion of the conductive material is removed to form a gate electrode (or a word line) within the opening defined by the dielectric layer. FIG. 5H illustrates the stage corresponding to operation 216.

The method 200 continues with operation 218 in which a dielectric structure, a bit line, and a capacitor structure are formed. As a result, a semiconductor device is produced. FIG. 5I and FIG. 5J illustrate the stage corresponding to operation 218.

The method 200 is merely an example, and is not intended to limit the present disclosure beyond what is explicitly recited in the claims. Additional operations may be provided before, during, or after each operation of the method 200, and some operations described may be replaced, eliminated, or reordered for additional embodiments of the method. In some embodiments, the method 200 may include further operations not depicted in FIG. 6. In some embodiments, the method 200 may include one or more operations depicted in FIG. 6.

One aspect of the present disclosure provides a semiconductor device. The semiconductor device includes a substrate, a dielectric layer, and a gate electrode. The dielectric layer is least partially embedded within the substrate. The dielectric layer has a first portion with a first thickness and a second portion with a second thickness less than the first thickness. The gate electrode is spaced apart from the substrate by the first portion of the dielectric layer.

Another aspect of the present disclosure provides a semiconductor device. The semiconductor device includes a substrate, a gate dielectric layer, a gate electrode, and a dielectric structure. The gate dielectric is embedded within the substrate. The gate electrode is spaced apart from the substrate by the gate dielectric. The dielectric structure is disposed over the gate electrode. The dielectric structure includes a step profile.

Another aspect of the present disclosure provides a method of manufacturing a semiconductor device. The method includes providing a substrate with a trench. The method also includes forming a dielectric layer with a first thickness within the trench. The method further includes removing an upper portion of the dielectric layer so that the upper portion of the dielectric layer has a second thickness less than the first thickness of a lower portion of the dielectric layer. In addition, the method includes forming a gate electrode within the trench.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a dielectric layer at least partially embedded within the substrate, wherein the dielectric layer has a first portion with a first thickness and a second portion with a second thickness less than the first thickness; and
a gate electrode spaced apart from the substrate by the first portion of the dielectric layer.

2. The semiconductor device of claim 1, wherein an upper surface of the first portion of the dielectric layer is higher than an upper surface of the substrate.

3. The semiconductor device of claim 1, wherein an upper surface of the first portion of the dielectric layer is substantially coplanar with an upper surface of the substrate.

4. The semiconductor device of claim 1, wherein an upper surface of the first portion of the dielectric layer is lower than an upper surface of the substrate.

5. The semiconductor device of claim 1, further comprising:
an isolation structure disposed on the substrate, wherein the isolation structure and the substrate collectively define a trench accommodating the dielectric layer.

6. The semiconductor device of claim 5, wherein the second portion of the dielectric layer is disposed on the isolation structure.

7. The semiconductor device of claim 6, wherein the second portion of the dielectric layer is further disposed on the substrate.

8. The semiconductor device of claim 1, wherein a ratio of the second thickness to the first thickness ranges from about 0.2 to about 0.8.

9. The semiconductor device of claim 1, wherein an upper surface of the first portion of the dielectric layer is substantially coplanar with an upper surface of the gate electrode.

10. The semiconductor device of claim 1, wherein an upper surface of the first portion of the dielectric layer is higher than an upper surface of the gate electrode.

11. The semiconductor device of claim 1, further comprising:
a bit line structure disposed over the substrate, wherein the gate electrode extends along a first direction, and the bit line structure extends along a second direction different from the first direction.

12. A semiconductor device, comprising:
a substrate;
a gate dielectric embedded within the substrate;
a gate electrode spaced apart from the substrate by the gate dielectric; and
a dielectric structure disposed over the gate electrode, wherein the dielectric structure includes a step profile.

13. The semiconductor device of claim 12, further comprising:
a dielectric layer connected to the gate dielectric and disposed within a trench of the substrate.

14. The semiconductor device of claim 13, wherein the dielectric layer has a first portion with a first thickness and a second portion with a second thickness different from the first thickness.

15. The semiconductor device of claim 14, wherein the dielectric structure is in contact with the first portion and the second portion of the dielectric layer.

16. The semiconductor device of claim 13, wherein an upper surface of the dielectric layer is higher than an upper surface of the substrate.

17. The semiconductor device of claim 13, wherein the dielectric structure has a first width and a second width different from the first width.

18. The semiconductor device of claim 17, wherein the dielectric structure has a T-shaped profile.

19. The semiconductor device of claim 17, wherein a ratio of the first width to the second width ranges from about 1.1 to 1.5.

20. The semiconductor device of claim 13, further comprising:
an isolation structure disposed on the substrate, wherein the isolation structure and the substrate collectively define the trench.
